(19) United States
(12) Patent Application Publication
(10) Pub. No.: US 2024/0113046 A1
(43) Pub. Date: Apr. 4, 2024

(54) EMBEDDED THIN FILM VARISTOR IN THROUGH GLASS VIAS

(71) Applicant: Intel Corporation, Santa Clara, CA (US)

(72) Inventors: Jason Scott Steill, Phoenix, AZ (US); Shayan Kaviani, Phoenix, AZ (US); Srinivas Venkata Ramanuja Pietambaram, Chandler, AZ (US); Suddhasattwa Nad, Chandler, AZ (US); Benjamin Duong, Phoenix, AZ (US); Srinivasan Raman, Chandler, AZ (US); Yi Yang, Gilbert, AZ (US)

(21) Appl. No.: 17/957,257

(22) Filed: Sep. 30, 2022

(51) Int. Cl. H01L 23/62; H01L 21/48; H01L 23/00; H01L 23/15; H01L 23/498; H01L 23/64

(52) U.S. Cl. CPC H01L 23/62; H01L 21/486; H01L 23/15; H01L 23/49827; H01L 23/49844; H01L 23/49894; H01L 23/642; H01L 23/645; H01L 23/647; H01L 24/24; H01L 2224/24145; H01L 2924/12036

(57) ABSTRACT

Various embodiments disclosed relate to embedded components in glass core layers for semiconductor assemblies. The present disclosure includes a semiconductor assembly with a glass core having one or more cavities and a component embedded into the glass core at the one or more cavities portion, the component at least partially embedded in the glass core, and a semiconductor die attached to the substrate.

### TECHNICAL FIELD

Embodiments described herein generally relate to semiconductor devices and

### BACKGROUND

An electronic device may include a semiconductor package, such as including an integrated circuit semiconductor die. The semiconductor package may be attached to or situated on a substrate or core material. Semiconductor package substrates can be made of a variety of materials. In some cases, glass-type substrates can be used. A variety of other active or passive components, in addition to connections such as via, may be situated on or in the substrate.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 depicts a semiconductor assembly including a glass core and an integrated component in an example.

FIG. 2 depicts a diode integrated into a glass core in an example.

FIGS. 3A-3B depict a thin film capacitor integrated into a glass core in an example.

FIGS. 4A-4B depict a thin film capacitor integrated into a glass core in an example.

FIGS. 5A-5B depict a resistor integrated into a glass core in an example.

FIG. 6 depicts a magnetic core inductor integrated in a glass core in an example.

FIG. 7 depicts a process flow for integrating a magnetic core inductor into a glass core in an example.

FIGS. 8A-8B depict a horizontal varistor integrated into a glass core in an example.

FIG. 9 depicts a process flow for integrating a horizontal varistor into a glass core in an example.

FIG. 10 depicts a process flow for integrating a horizontal varistor into a glass core in an example.

FIG. 11 depicts a process flow for integrating a vertical varistor into a glass core in an example.

FIG. 12 depicts a system in which a glass core with an integrated component can be used.

FIG. 13A depicts a transistor on a glass core in an example.

FIG. 13B depicts a method of making a transistor on a glass core in an example.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

The present disclosure provides a method of patterning a glass core to allow for filling of those patterns and integration of electronic components to the glass core. Such components can include resistors, capacitors, and inductors. In some cases, such patterning methods can be used to integrate horizontal or vertical varistors into the glass core. This can allow for a smaller footprint overall.

Semiconductor assemblies, such as including microprocessors, can include power regulation. Such power regulation can be provided, for example, by power delivery circuits or other passive components. However, the integration of power delivery circuits, or other passive components, into semiconductor assembly substrates can be challenging. With organic type substrates, these components could not be integrated into the organic substrate itself. Mounting power delivery circuits or other passive components on a substrate can take up a large amount of space in the semiconductor package.

Glass cores have been increasingly used in semiconductor assemblies. These glass type substrates can be patterned to allow for inbuilt components therein. This can enable power regulation with a smaller semiconductor assembly footprint. For example, power delivery circuits, or other passive components, can be embedded in such a glass core material. Patterning a glass core material (e.g., a glass core) can allow for deposition and filling the patterns to form integrated electronic components such as resistors, capacitors, and inductors. These components can be connected within the semiconductor package and act as power regulation circuits. These power regulation circuits can be identified in a cross section of the glass core.

Moreover, power delivery requirements may involve segmentation of voltage stabilization, such as due to different die regions. Similarly, power delivery requirements may entail horizontal or vertical varistors for power regulation in a semiconductor assembly. In some semiconductor assemblies, discrete varistor components have been used in cavities, bump layers, or on routing layers (e.g., as planar thing film varistors). However, these types of components are bulky and take up a large amount of room in a semiconductor assembly.

Discussed herein, segmentation of voltage stabilization can be addressed by using thin film varistors (TFV) in through glass via (TGV) of glass core materials. This can help enable voltage stabilization with a reduced package size. For example, TFV can be integrated or embedded in a glass core. Energy dispersive spectroscopy could be used to detect such TFV.

In some cases, a horizontal varistor can be deposited into a glass core. The horizontal varistor can help in voltage regulation for power delivery to various semiconductor dies, thereby helping to protect them from voltage spikes. In some cases, varistors made of multiple materials can be added in parallel to provide a protection against a range of voltage spikes. This can be done, for example, by glass etching and filling the varistor circuit inside a glass core. Embedded components can reduce the desire for mounting external components at the end of substrate manufacturing. Energy dispersive spectroscopy or SEM imagine could be used to detect such horizontal varistors.

The discussed methods and system provide several advantages, some of which are unexpected. Integrated components in glass cores can provide opportunities and possibilities for moving power regulation circuits within the semiconductor assembly, such as away from dies. This can allow additional space on silicon portions of the assembly, such as to add circuits for computations. Moreover, components integrated into the glass core can help reduce connections on semiconductor package layers, as power regulation circuitry would not be distributed between the package substrate and silicon dies.

Moreover, by depositing TFVs in vertical TGV features, voltage stabilization can be performed without taking up real estate for patterning or other components on build up and bump layers. Embedded varistors can provide voltage regulation and help to remove voltage spikes, thereby acting as a first line of defense for the microprocessor on a package side. Varistors can be fast acting over-voltage protection devices with response times in the order of nanoseconds. This can be useful, as input voltage and current frequencies can be the order of 10-100 Hz. Such varistors can be configured for wide range of breakdown voltages.

In an example, a semiconductor assembly can include: a glass core, the substrate comprising a patterned portion; a component integrated into the glass core at the patterned portion, the component at least partially embedded in the glass core; and a semiconductor die attached to the substrate.

In an example, a semiconductor substrate can include: a glass core having a first patterned portion and a second patterned portion, each of the patterned portions filled with a conductive material; a component embedded in the glass core, the component extending between the first patterned portion and the second patterned portion, wherein the component is electrically connected through the conductive material.

In an example, a method of making a semiconductor assembly can include etching a portion of a glass core to produce one or more patterned portions therein; filling the one or more patterned portions with a conductive material; and at least partially embedding a component in the glass core, the component connected to the one or more patterned portions.

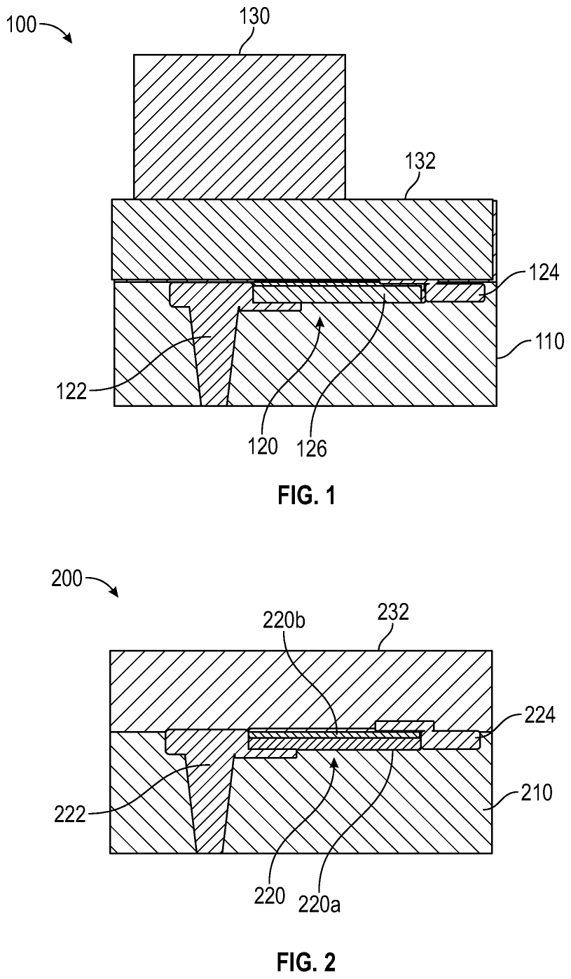

FIG. 1 depicts a semiconductor assembly 100 including a glass core 110 and an integrated component 120 in an example. In the assembly 100, the glass core 110 can host a build-up layer 132 and a semiconductor die 130. The integrated component 120 can be electrically connected with first point 122 and second point 124.

The glass core 110 can be, for example, a substrate material in the semiconductor assembly 100. The glass core 110 can be a borosilicate glass, a coated glass, or another suitable type of glass material. The glass core 110 can be patterned, such as to contain one or more cavities for the integrated component 120.

The integrated component 120 can include the first point 122 and the second point 124, in addition to the component 126. The component 126 can be at least partially embedded into the glass core 110 such that the component 126 is integrated into the glass core 110 rather than being mounted on substrate surface. This can allow for more room on a substrate surface in the semiconductor assembly 100 for other components.

In the example integrated component 120, the first point 122 and the second point 124 can be metallic or otherwise conductive filler material. The filler material can be, for example, strontium titanium oxide, barium strontium titanate, or combinations thereof. In some cases, the integrated component 120 can be made of a magnetic paste or ink.

The first point 122 and the second point 124 can be connections for the integrated component 120, such as connections to ground, connections to power, or otherwise electrical connections between the component 126 and other parts of the semiconductor assembly 100.

The semiconductor die 130 can be situated on the semiconductor assembly 100 on a build-up layer 132. The build-up layer 132 can include a multitude of layers, such as of a dielectric, and connections, such as metallic traces, via, or other variants, to allow connection between the glass core 110 and the components therein and the semiconductor die 130. The semiconductor die 130 can, for example, be an electronic integrated circuit.

FIGS. 2 to 6 below depict examples of types of components that might be integrated into and embedded in a glass core such as the glass core 110. The assemblies shown and discussion with reference to FIGS. 2 to 6 can contain similar components to those in FIG. 1, except as otherwise noted.

FIG. 2 depicts an assembly 200 with a diode 220 integrated into a glass core 210 in an example. The diode 220 can include a first diode side 220a and a second diode side 220b. The diode 220 can be, for example, a P-N junction diode. The first diode side 220a can be a first material, and the second diode side 220b can be a second material, such that the first material is a p side (positive doped), and the second material is an n side (negative doped). In assembly 200, the diode 220 can be electrically connected in the assembly 200 through the first point 222 and the second point 224. The first point 222 can be electrically connected to the diode 220 through the first diode side 220a, while the second point 224 can be electrically connected to the diode 220 through the second diode side 220b. The diode 220 can be at least partially embedded in the glass core 210. A buildup layer 232 can be situated on top of the glass core 210.

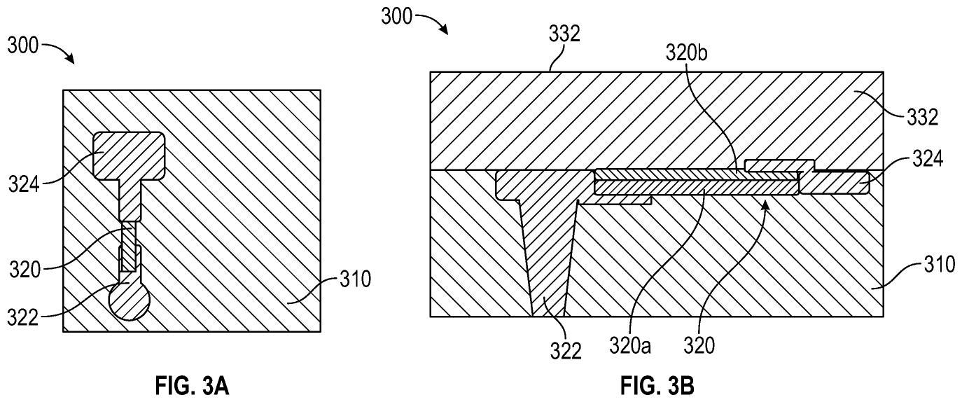

FIGS. 3A-3B depict an assembly 300 with a thin film capacitor 320 integrated into a glass core 310 in an example. FIG. 3A depicts an illustration of a top-down view, while FIG. 3B depicts an illustration of a cross-sectional view. The thin film capacitor 320 of the assembly 300 can include a first side 320a and a second side 320b. In the assembly 300, the thin film capacitor 320 can have two layers, and be connected through first conduction point 322 and second conduction point 324.

FIGS. 4A-4B depict an assembly 400 with a thin film capacitor 420 integrated into a glass core 410 in an example. FIG. 4A depicts an illustration of a top-down view, while FIG. 4B depicts an illustration of a cross-sectional view. The thin film capacitor 420 can include a first side 420a and a second side 420b. In the assembly 400, the thin film capacitor 420 can have two layers, and be connected through first conduction point 422 and second conduction point 424.

The thin film capacitor 320 and the thin film capacitor 420 can be at least partially embedded in their respective glass cores. A buildup layer 332, 432 can be situated on top of the glass core 310, 410. Shown in FIGS. 3A and 4A, the thin film capacitor 320 can have a smaller footprint than the thin film capacitor 420. In some cases, such as thin film capacitor can have a lower capacitance; in others, the thin film capacitor can have a higher capacitance.

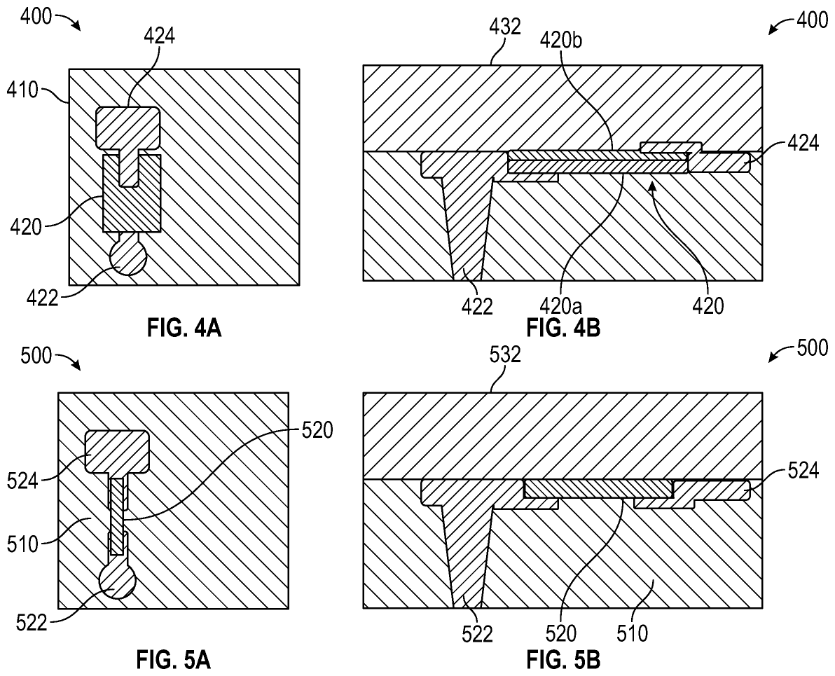

FIGS. 5A-5B depict an assembly 500 with a resistor 520 integrated into a glass core 510 in an example. FIG. 5A depicts an illustration of a top-down view, while FIG. 5B depicts an illustration of a cross-sectional view. The resistor 520 can be connected within the assembly 500 through a first conduction point 522 and a second conduction point 524. The resistor 520 can be at least partially embedded in the glass core 510. A buildup layer 532 can be situated on top of the glass core 510.

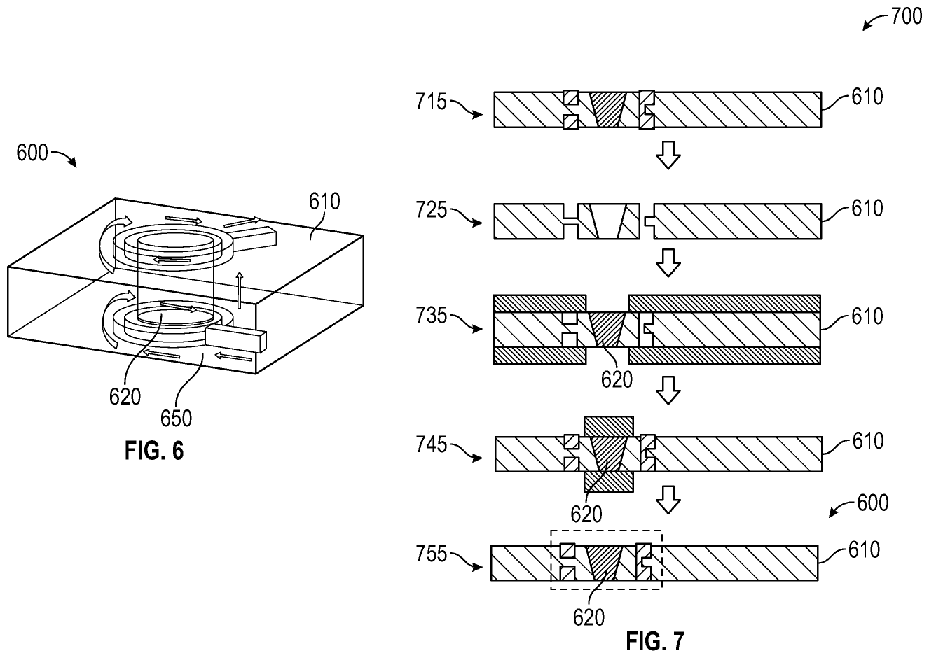

FIG. 6 depicts an assembly 600 with a magnetic core inductor 620 integrated in a glass core 610 in an example. The magnetic core inductor 620 can be, for example, a coil inductor, such as a two-turn or three-turn inductor. Current flow around the inductor is shown by arrows 650. Here, the magnetic core inductor 620 can be at least partially embedded in the glass core 610.

Similarly, FIG. 7 depicts a process flow 700 for integrating a magnetic core inductor 620 into a glass core 610 in an example. At block 715, glass via (TSV) 615 and the magnetic core inductor 620 can be patterned in the glass core 610, such as by phase changing a portion of the glass core 610. In some cases, this can be done through infrared laser.

Next, at block 725, cavities for the TSV 615 and the magnetic core inductor 620 can be etched out from the patterned areas. At block 735, the TSV 615 can be masked, such as with lithography, and the magnetic core inductor 620 can be filled. For example, the magnetic core inductor 620 can be filled with a magnetic paste or ink to form the magnetic core inductor 620. At block 745, the magnetic core inductor 620 can be masked, such as by lithography, and the TSV 615 can be filled with the appropriate material. The mask(s) can then be removed at block 755 to produce the glass core 610 with the magnetic core inductor 620.

Any of the components discussed with reference to FIGS. 2 to 7 above, such as the diode 220, the thin film capacitor 320, the thin film capacitor 420, the resistor 520, or the magnetic core inductor 620, can be built into a glass core through similar patterning, etching, and filling techniques. These types of components can be used, for example, to build power and voltage regulation circuits embedded in the glass core, so as to free up space on the surface of the glass core for other layers or components. For example, using glass core embedded diodes, inductors, capacitors, and resistors can be used to build embedded bridge rectifiers, embedded filters for power noise reduction, asynchronous inductor-based switch regulators, synchronous inductor-based switch regulators, or other configurations.

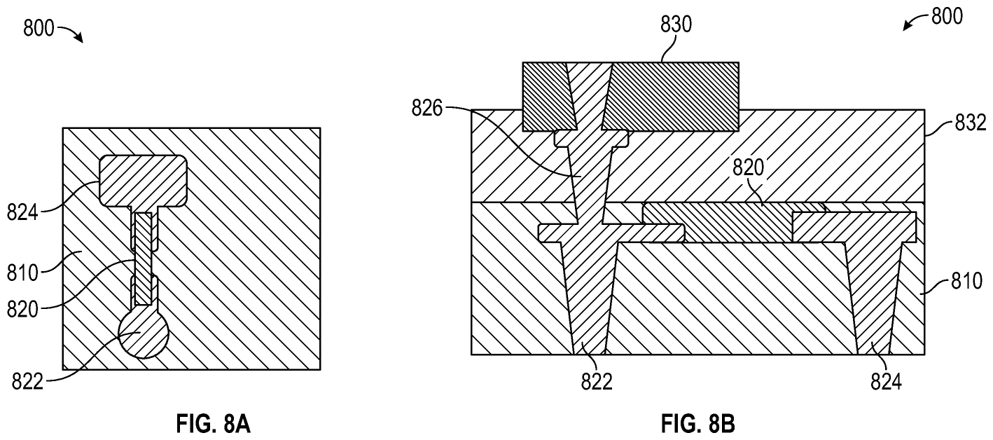

FIGS. 8A to 11 below and the corresponding discussion are related to the use of varistors in glass core layers. In some examples, horizontal varistors are integrated into the glass core layer. In some cases, vertical varistors are integrated into the glass core layers. In both iterations, the glass core layer can be patterned as desired, and filled to produce connections such as ground or power delivery circuits. The varistors can be integrated into these power circuits or connected to them.

Varistors can be used in such semiconductor assemblies in a variety of ways. Varistors can generally have electrical resistance that varies with the applied voltage. Particular materials can be used to create varistors within a semiconductor assembly. Discussed here are examples of both horizontal varistors and vertical varistors for use in a semiconductor assembly having a glass core. In either case, the varistors can be at least partially embedded into the glass core.

FIGS. 8A-8B depict an assembly 800 with a horizontal varistor 820 integrated into a glass core 810 in an example. The assembly 800 can include the glass core 810, the horizontal varistor 820, in addition to the filled portion 822, filled portion 824, connection 826, build up 828, and semiconductor die 830. Many of the components of the assembly 800 can be similar to those described with reference to FIG. 1 above.

The at least partially embedded component can be the horizontal varistor 820, which can help provide voltage regulation and help to remove voltage spikes, thereby acting as a first line of defense for a microprocessor on a package side of the assembly. Such varistors can be fast acting over-voltage protection devices with response times in the order of nanoseconds, which are useful since input voltage and current frequencies are in the order of 10-100 Hz. Here, the horizontal varistor 820 can act as a shunt from the 830/to ground through the filled portion 822. The filled portion 824 and connection 826 can be, for example, a power via.

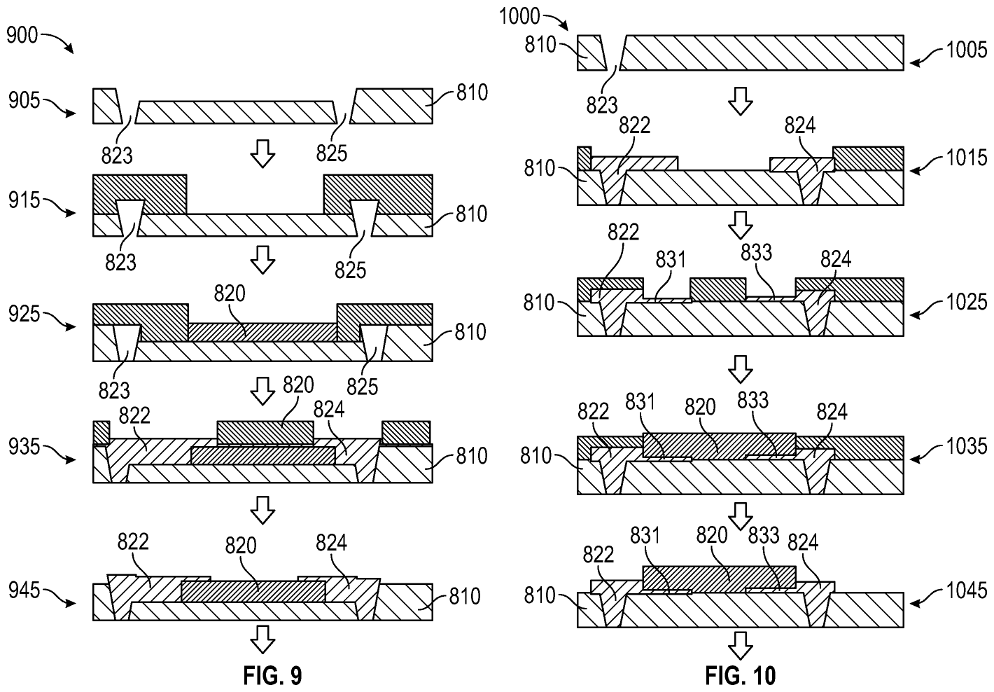

FIG. 9 depicts a process flow 900 for integrating a horizontal varistor 820 into a glass core 810 in an example. FIG. 10 depicts an alternative process flow 1000 for integrating a horizontal varistor 820 into a glass core 810 in an example. The assembly built in process flow 900 or 1000 can include the glass core 810 with the horizontal varistor 820 situated between filled portion 822 and filled portion 824.

Overall, both process flows 900 and 1000 can be used to produce an at least partially embedded horizontal varistor in a glass core, such as for use as a shunt to ground.

In process 900, at block 905, power TGV 823 and ground TGV 825 can be created in the glass core 810, such as through etching or drilling. The TGV 823 can correlate to the later filled portion 822. The TGV 825 can correlate to the later filled portion 824.

At block 915 after through TGV 823 and TGV 825 for power and ground are etched, they can be masked, such as by lithography. At block 925, the varistor material for the horizontal varistor 820 can be deposited between the mask. Such a varistor material can include, for example, zinc oxide, dopants, and appropriate fillers.

At block 935, the TGV 823 and TGV 825 can be filled with copper, such as by seeded copper and copper filling. Traces can also be deposited at this time. Selective masking, such as by lithography, can be used to cover at least a portion of the horizontal varistor 820. The TGV can be filled to form the filled portion 822 and the filled portion 824. At block 945, the mask can be removed. Subsequently, at block 955, other build-up layers can be situated onto the glass core 810.

In the process flow 1000, at block 1005, TGV 823, 825 can be made, such as by drilling, in the glass core 810. At block 1015, the TGV 823, 825, can be filled, such as by copper. Metallic traces can also be filled with copper. Lithography patterning can be used to allow selective filling. This can produce the filled portion 822 and the filled portion 824.

At block 1025, additional lithography patterning can be used to deposit copper electrodes 831, 833, extending from the filled portion 822 and filled portion 824. Following this, at block 1035, the horizontal varistor 820 can be deposited between the electrodes 831 and 833. The varistor material can include, for example, zinc oxide, and dopants, such as Bi₂O₃, Sb₂O₃, Co₃O₄, MnO, NiO and Cr₂O₃. At block 1045, resist can be removed, and at block 1055, continued build-up of the assembly can continue.

The assembly built in process flows 900 and 1000 can include a horizontal varistor 820 that is at least partially embedded in the glass core 810. The horizontal varistor 820 can be electrically connected to one or more semiconductor dies to allow for power circuit regulation, and potentially as a ground shunt.

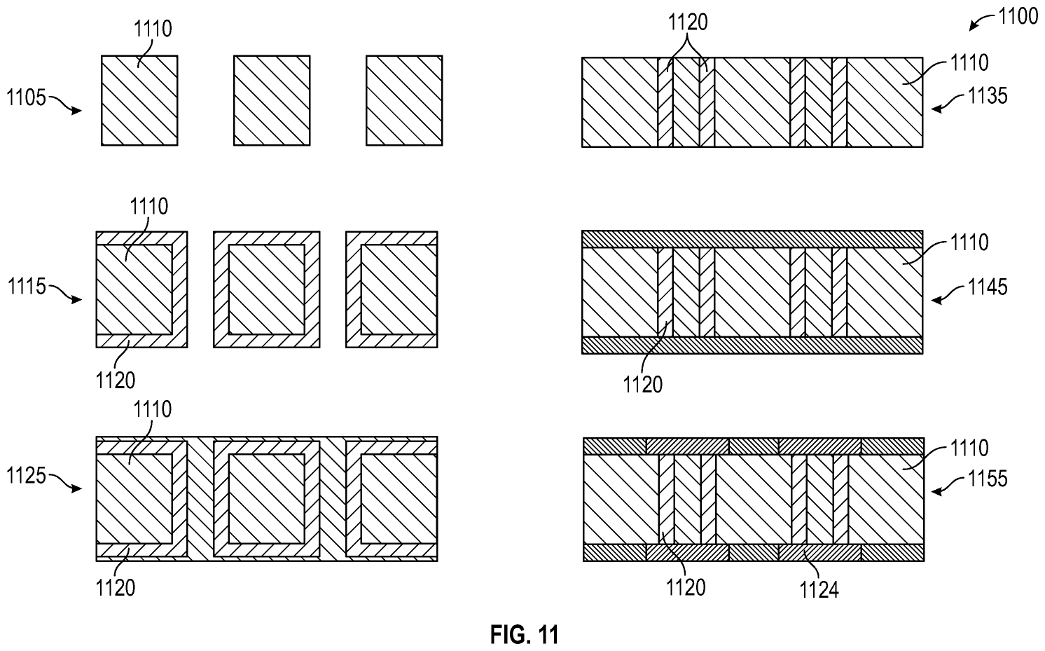

FIG. 11 depicts a process flow 1100 for integrating a vertical varistor 1120 into a glass core 1110 in an example. The assembly built in process flow 1100 can include the glass core 1110 having the vertical varistors 1120 in via 1122, connection pads 1124, and dielectric layer 1126. The glass core 1110 can be similar to the glass cores describes above, such as the glass core 110 discussed with reference to FIG. 1.

The vertical varistors 1120 can be situated in through glass via (TGV) 1122. Having the vertical varistors 1120 in the TGV 1122 can allow for improved power delivery circuit performance and regulation in a semiconductor assembly. Discussed here is deposition of Thin Film Varistors (TFV) in Through Glass Vias (TGVs) to allow voltage stabilization at reduced footprints. In some cases, Atomic Layer Deposition (ALD) can be used can allow for extending deposition of TFVs into increasing Aspect Ratios (ARs).

At block 1105, TGV can be made, such as by drilling or etching, in the glass core 1110. At block 1115, thin film varistor material can be deposited in the TGV to form vertical varistors 1120. The varistor material can include, for example, zin oxide with a ceramic binder, cobalt/zinc oxide nano particles, zinc oxide thin layers with thin layers of cobalt, or other appropriate materials. Thickness and material choice for conductive metal and TFV features can be chosen per desired voltage stabilization requirements.

At block 1125, a plug material can be deposited into the TGV with the vertical varistors 1120. The plug material can be a paste application, such as an insulating dielectric. In some cases, other deposition techniques can be used, for example, a silicon dioxide can be deposited by chemical vapor deposition. In some cases, individual TGV that do not need a varistor material can be pre-plugged.

At block 1135, planarization can be done to isolate the TGV with the vertical varistors 1120. At block 1145, a dielectric material can be built up into the dielectric layer 1126, such as for routing and pads, as desired for the semiconductor assembly 1100.

At block 1155, lithography and plating can be used to reveal the filled TGV with vertical varistors 1120. The connection pads 1124 can be deposited onto ends of the TGV 1122, such as with a metallic material. Dielectric lamination can be continued, and the TGV 1122 with the vertical varistors 1120 can be electrically connected from the connection pads 1124.

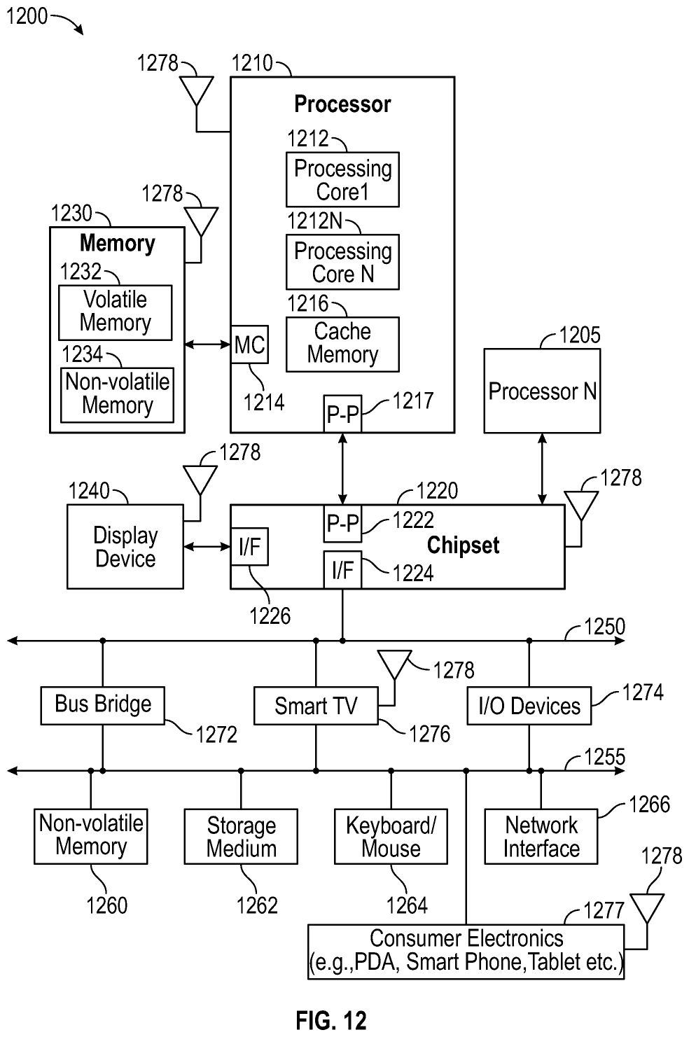

FIG. 12 illustrates a system level diagram, depicting an example of an electronic device (e.g., system) that may include a PIC and a glass recirculatory and/or methods described above. In one embodiment, system 1200 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 1200 includes a system on a chip (SOC) system.

In one embodiment, processor 1210 has one or more processor cores 1212 and 1212N, where 1212N represents the Nth processor core inside processor 1210 where N is a positive integer. In one embodiment, system 1200 includes multiple processors including 1210 and 1205, where processor 1205 has logic similar or identical to the logic of processor 1210. In some embodiments, processing core 1212 includes, but is not limited to, pre-fetch logic to fetch instructions, decode logic to decode the instructions, execution logic to execute instructions and the like. In some embodiments, processor 1210 has a cache memory 1216 to cache instructions and/or data for system 1200. Cache memory 1216 may be organized into a hierarchal structure including one or more levels of cache memory.

In some embodiments, processor 1210 includes a memory controller 1214, which is operable to perform functions that enable the processor 1210 to access and communicate with memory 1230 that includes a volatile memory 1232 and/or a non-volatile memory 1234. In some embodiments, processor 1210 is coupled with memory 1230 and chipset 1220. Processor 1210 may also be coupled to a wireless antenna 1278 to communicate with any device configured to transmit and/or receive wireless signals. In one embodiment, an interface for wireless antenna 1278 operates in accordance with, but is not limited to, the IEEE 802.11 standard and its related family, Home Plug AV (HPAV), Ultra-Wide Band (UWB), Bluetooth, WiMAX, or any form of wireless communication protocol.

In some embodiments, volatile memory 1232 includes, but is not limited to, Synchronous Dynamic Random Access Memory (SDRAM), Dynamic Random Access Memory (DRAM), RAMBUS Dynamic Random Access Memory (RDRAM), and/or any other type of random-access memory device. Non-volatile memory 1234 includes, but is not limited to, flash memory, phase change memory (PCM), read-only memory (ROM), electrically erasable programmable read-only memory (EEPROM), or any other type of non-volatile memory device.

Memory 1230 stores information and instructions to be executed by processor 1210. In one embodiment, memory 1230 may also store temporary variables or other intermediate information while processor 1210 is executing instructions. In the illustrated embodiment, chipset 1220 connects with processor 1210 via Point-to-Point (PtP or P-P) interfaces 1217 and 1222. Chipset 1220 enables processor 1210 to connect to other elements in system 1200. In some embodiments of the example system, interfaces 1217 and 1222 operate in accordance with a PtP communication protocol such as the Intel® Quick Path Interconnect (QPI) or the like. In other embodiments, a different interconnect may be used.

In some embodiments, chipset 1220 is operable to communicate with processor 1210, 1205N, display device 1240, and other devices, including a bus bridge 1272, a smart TV 1276, I/O devices 1274, nonvolatile memory 1260, a storage medium (such as one or more mass storage devices) 1262, a keyboard/mouse 1264, a network interface 1266, and various forms of consumer electronics 1277 (such as a PDA, smart phone, tablet etc.), etc. In one embodiment, chipset 1220 couples with these devices through an interface 1224. Chipset 1220 may also be coupled to a wireless antenna 1278 to communicate with any device configured to transmit and/or receive wireless signals. In one example, any combination of components in a chipset may be separated by a continuous flexible shield as described in the present disclosure.

Chipset 1220 connects to display device 1240 via interface 1226. Display 1240 may be, for example, a liquid crystal display (LCD), a light emitting diode (LED) array, an organic light emitting diode (OLED) array, or any other form of visual display device. In some embodiments of the example system, processor 1210 and chipset 1220 are merged into a single SOC. In addition, chipset 1220 connects to one or more buses 1250 and 1255 that interconnect various system elements, such as I/O devices 1274, nonvolatile memory 1260, storage medium 1262, a keyboard/mouse 1264, and network interface 1266. Buses 1250 and 1255 may be interconnected together via a bus bridge 1272.

In one embodiment, mass storage device 1262 includes, but is not limited to, a solid-state drive, a hard disk drive, a universal serial bus flash memory drive, or any other form of computer data storage medium. In one embodiment, network interface 1266 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra-Wide Band (UWB), Bluetooth, WiMAX, or any form of wireless communication protocol.

While the modules shown in FIG. 12 are depicted as separate blocks within the system 1200, the functions performed by some of these blocks may be integrated within a single semiconductor circuit or may be implemented using two or more separate integrated circuits. For example, although cache memory 1216 is depicted as a separate block within processor 1210, cache memory 1216 (or selected aspects of 1216) can be incorporated into processor core 1212.

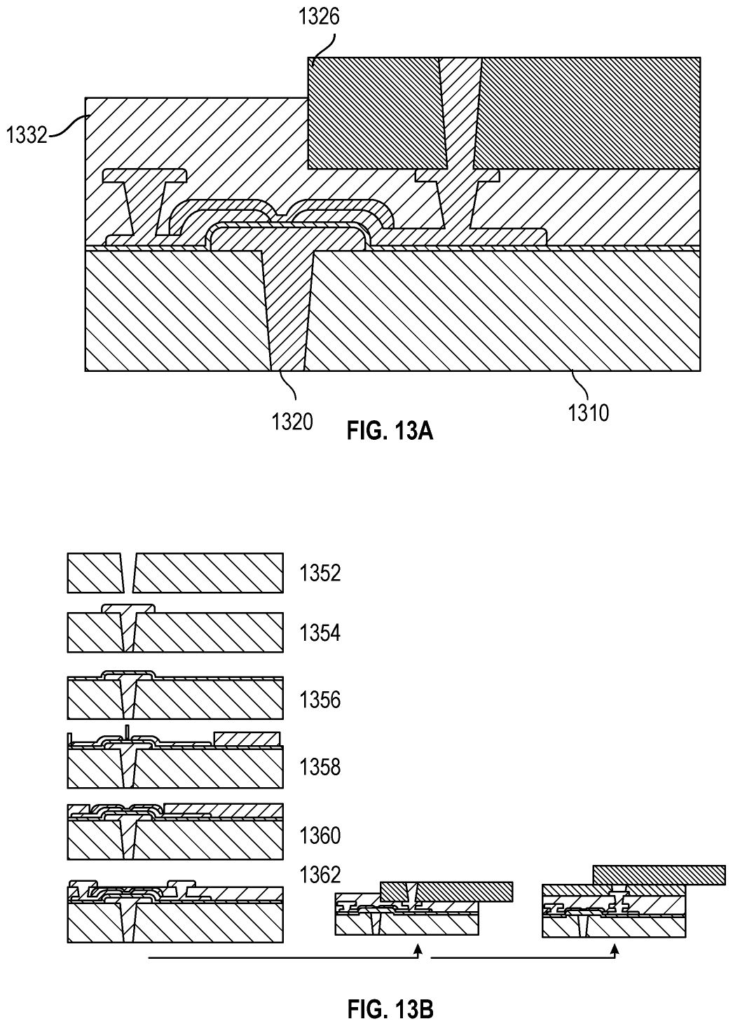

FIG. 13A depicts a transistor 1320 on a glass core 1310. FIG. 13B depicts a method 1350 of making such a transistor 1320 on the glass core 1310. In FIG. 13A, a representation of a cross-section of the assembly 1300 can include the glass core 1310, the transistor 1320, a build-up layer 1332, and a semiconductor die 1326.

FIG. 13B depicts a method. The method can include creating through glass via in a glass core (1352), plating the through glass via (1354), deposition of a silicon nitride layer (1356), deposition of copper pads (1358), deposition of a channel (1360), and buildup and attachment of a die (1362).

### Various Notes & Examples

Each of these non-limiting examples can stand on its own or can be combined in various permutations or combinations with one or more of the other examples.

Example 1 is a semiconductor assembly comprising: a glass core, the substrate comprising a patterned portion; a component integrated into the glass core at the patterned portion, the component at least partially embedded in the glass core; and a semiconductor die attached to the substrate.

In Example 2, the subject matter of Example 1 optionally includes a conductive fill in the patterned portion, the conductive fill configured to electrically connect to the component.

In Example 3, the subject matter of any one or more of Examples 1-2 optionally include wherein the patterned portion comprises a first conduction point and a section conduction point, the component connected therebetween.

In Example 4, the subject matter of any one or more of Examples 1-3 optionally include wherein a surface of the component lies flush with a surface of the glass core, and the component is embedded in the glass core.

In Example 5, the subject matter of any one or more of Examples 1-4 optionally include wherein the component comprises a diode.

In Example 6, the subject matter of Example 5 optionally includes wherein the diode comprises a P-N junction diode.

In Example 7, the subject matter of any one or more of Examples 1-6 optionally include wherein the component comprises a capacitor.

In Example 8, the subject matter of Example 7 optionally includes wherein the capacitor comprises a low capacitance thin-film capacitor.

In Example 9, the subject matter of any one or more of Examples 7-8 optionally include wherein the capacitor comprises a high capacitance thin-film capacitor.

In Example 10, the subject matter of any one or more of Examples 1-9 optionally include wherein the component comprises a resistor.

In Example 11, the subject matter of any one or more of Examples 1-10 optionally include wherein the component comprises an inductor.

In Example 12, the subject matter of Example 11 optionally includes wherein the inductor comprises a magnetic core inductor.

In Example 13, the subject matter of Example 12 optionally includes wherein the inductor comprises a two-turn magnetic core inductor.

In Example 14, the subject matter of any one or more of Examples 1-13 optionally include wherein the component comprises strontium titanium oxide, barium strontium titanate, or combinations thereof.

In Example 15, the subject matter of any one or more of Examples 1-14 optionally include wherein the component comprises ajinonomoto magnetic paste.

Example 16 is a semiconductor substrate comprising: a glass core having a first patterned portion and a second patterned portion, each of the patterned portions filled with a conductive material; a component embedded in the glass core, the component extending between the first patterned portion and the second patterned portion, wherein the component is electrically connected through the conductive material.

In Example 17, the subject matter of Example 16 optionally includes wherein the component comprises a capacitor, a diode, a resistor, a transistor, or an inductor.

Example 18 is a method of making a semiconductor assembly comprising: etching a portion of a glass core to produce one or more patterned portions therein; filling the one or more patterned portions with a conductive material; and at least partially embedding a component in the glass core, the component connected to the one or more patterned portions.

In Example 19, the subject matter of Example 18 optionally includes wherein embedding a component in the glass core comprises etching a secondary patterned portion and filling the patterned portion with an inductor material.

In Example 20, the subject matter of any one or more of Examples 18-19 optionally include wherein etching a portion of a glass core comprises infrared laser phase change.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor assembly comprising:
a glass substrate comprising:
a via extending through the substrate, wherein the internal surface of the via is coated in a material comprising a cobalt, zinc, and oxygen material;
a conductive pad on an end of the via; and
a semiconductor die attached to the glass substrate.

2. The semiconductor assembly of claim 1, further comprising a material in the via.

3. The semiconductor assembly of claim 2, wherein the material in the via comprises an insulating dielectric paste.

4. The semiconductor assembly of claim 2, wherein the filler material comprises a silicon and oxygen.

5. The semiconductor assembly of claim 1, wherein the conductive pad lies flush with a surface of the glass substrate.

6. The semiconductor assembly of claim 1, wherein the material has a resistance variable with applied voltage.

7. The semiconductor assembly of claim 6, wherein the material having a resistance variable with applied voltage comprises a thin film.

8. The semiconductor assembly of claim 1, wherein the conductive pad comprises a metallic pad.

9. The semiconductor assembly of claim 8, wherein the metallic pad comprises copper.

10. The semiconductor assembly of claim 1, further comprising a dielectric layer on a surface of the glass substrate.

11. The semiconductor assembly of claim 10, wherein the dielectric layer isolates the metallic pad.

12. The semiconductor assembly of claim 1, wherein the material forms a vertical varistor.

13. A semiconductor substrate comprising:
a glass core substrate comprising:
at least one through glass via extending through the substrate, the at least one through glass via containing a vertical varistor comprising a material having a resistance variable with applied voltage extending along the through glass via, and
end pads at each terminating end of the through glass via; and
circuitry couple to the component to operate the material as a varistor.

14. The semiconductor substrate of claim 13, wherein the through glass via further contains a filler material at least partially encapsulated by the varistor.

15. The semiconductor substrate of claim 13, wherein the vertical varistor is embedded in the glass core substrate.

16. A method of making a semiconductor assembly comprising:
making a through glass via in a glass core layer;
coating inside the through glass via with a material having a resistance variable with applied voltage to form a vertical varistor;
plugging inside the through glass via to define the vertical varistor;
planarizing the vertical varistor;
depositing a dielectric layer on a surface of the glass core layer where the varistor terminates; and
depositing a metallic pad on the dielectric layer where the varistor terminates.

17. The method of claim 16, wherein making a through glass via comprises drilling.

18. The method of claim 16, wherein making a through glass via comprises etching.

19. The method of claim 16, wherein plugging comprises using an insulating dielectric material.

20. The method of claim 16, wherein plugging comprises chemical vapor deposition.
